(19) United States
(12) Patent Application Publication
(10) Pub. No.: US 2026/0299466 A1
(43) Pub. Date: Oct. 1, 2026

(54) METHOD OF ETCHING A SUBSTRATE

(71) Applicants: The Gillette Company LLC, Boston, MA (US); Gesellschaft für Diamantprodukte mbH, Neu-Ulm (DE)

(72) Inventors: Peter Bodo Gluche, Bellenberg (DE); Matthias Gester, Farnborough (GB)

(21) Appl. No.: 19/461,942

(22) Filed: Jan. 28, 2026

Related U.S. Application Data
(60) Provisional application No. 63/750,552, filed on Jan. 28, 2025.

(51) Int. Cl. G03G 15/16; H10P 50/00; H10W 72/00

(52) U.S. Cl. CPC G03G 15/162; H10P 50/73; H10W 72/0198

(57) ABSTRACT

The present invention relates to a method of etching a substrate. The method comprises providing a substrate and a structure transfer member. Prior to etching, the structure transfer member will have a profile. The etching transfers the profile from the structure transfer member to the substrate by simultaneously etching both materials.

### FIELD OF THE INVENTION

The present invention relates to a method of etching a substrate using a structure transfer member. The method may be used to etch cutting blades.

### BACKGROUND OF THE INVENTION

Cutting blades for shaving are typically made from steel and have a straight linear shape. The mechanical grinding process creates edges that are rough and have a tip radius on the order of 30 nm. Additionally, mechanical grinding processes are further limited to forming blades that have straight linear edges.

Another means of making edges is through the use of wet chemical etching. However, wet chemical etching of metal blades results in tip radii that are on the order of 500 nm or greater (EP 3908684) and therefore are not sharp enough to cut hair in cantilever mode cutting like in wet shaving, that is without a counter edge as it is found in scissor action cutting.

Non-protruding enclosed edges with tip radii less than 50 nm in a silicon substrate have been disclosed (U.S. Pat. No. 7,124,511), however, these edges have been found to be too brittle to cut through hair in cantilever mode cutting. Also, the anisotropic etching of crystalline silicon results in specific crystallographic planes that result in specific angles relative to the substrate surface across the blade thickness (z-direction), which limits the design flexibility of the edge profile. Isotropic etching of silicon results in curved bevel profiles having undesirable and variable angles.

Furthermore, all blade making techniques for blade making today are limited to fixed symmetries. In the case of traditional grinding of steel blades this symmetry is unidirectional linear. In the case of circular enclosed apertures (EP3908684,U.S. Pat. No. 52,93,768), the symmetry is axial rotational and in the case of e.g. silicon (100) (U.S. Pat. No. 7,124,511) it is four-fold in the plane. Not being limited by the process or material, symmetry allows for the fabrication of blades that can be uniquely adopted to the method of use (strokes in multiple but specific directions over the skin) and different hair types and body sites to be shaved. Furthermore, all state-of-the-art fabrication methods limit the bevel profile design to monotonically increasing bevel. The bevel profile design is thus very limited by the fabrication method. The 3-dimensional structuring of silicon is commonly done by applying a mask (e.g. hard mask and or photoresist) onto the surface of a silicon substrate. The mask contains openings through which reactive etchants (e.g. reactive chemicals) can reach the silicon substrate surface and etch away the silicon material. This results typically in structures that have a depth depending on the duration and the rate of the etching process. The side wall profile is either curved shaped (due to the isotropy of the etching process that attacks also laterally) or perpendicular to the silicon substrate surface (if additional side wall protection steps/passivation are implemented). Hard masks included silicon nitride Si₃N_{4,} silicon oxide SiO₂, or metals. The openings in the hard masks are typically produced using photolithography. Etching may be performed using dry etching methods such as RIE (reactive ion etching−typically capacitive coupled plasmas) or DRIE (deep reactive ion etching—typically ICP—inductive coupled plasma). Dry etching is always nearly independent from the crystal orientation and typically isotropic-leading to curved profiles. Since there's a need for straight vertical sidewalls in MEMS (micro electromechanical systems) technology, the isotropy (lateral etching direction) is suppressed by passivation steps. Thus, alternating short isotropic etching steps are followed by passivation steps that protect the sidewall. The result is a quasi-vertical sidewall profile having a scalloped side wall micro profile.

This approach is used for creating trenches, holes, or more complex shapes such as gear wheels for MEMS systems. This technique is not able to produce structures in the silicon substrate that have surfaces at straight or defined variable angels with respect to the substrate surface (except for isotropic, curved profiles). Furthermore, hard masks are not completely resistant to the etching ions, and the mask needs to be removed (stripped) in a separate process step after the structuring of the silicon is complete. To obtain structures in a silicon substrate with surfaces that are not perpendicular to the substrate surface, typically anisotropic wet chemical etching of silicon along crystallographic planes is used. In this case, also a hard mask with openings is required through which a wet etchant, typically KOH or TMAH plus additives, can reach the silicon substrate surface and etch away the silicon material. The depth and the 3-dimensional shape of the resulting structure depend on the duration and the rate of etching, because some crystallographic planes etch away faster than others. The 3-dimensional shapes that can be produced in the silicon substrate are limited by the crystallographic orientation of the silicon substrate. In consequence, only certain angles can be obtained given by the orientation of the crystal planes. For the lateral geometry, it is also not possible to create structures with smoothly curved, e.g. circular, or oval shapes. Finally, surfaces of the etched structures must slope away from the substrate surface into the depth of the silicon substrate, they cannot alter the direction of slope.

Hence there is a need to produce a mechanically sufficiently strong, sharp and smooth edge with design freedom of the edge profile/bevel across the blade thickness (z-direction) (preferably made of silicon of any crystallinity) having two-dimensional planar shapes and without any geometrical limitations in the lateral blade plane (xy-plane). Ideally, without mechanical grinding or wet chemical processing that can be stabilized with a thin hard coating such as NCD (nano crystalline diamond).

### SUMMARY OF THE INVENTION

The present invention is directed to a method of etching a substrate, the method comprising the steps of providing a substrate, providing a structure transfer member having a profile, placing the structure transfer member in contact with the substrate, and etching the substrate and the structure transfer member simultaneously thereby transferring the profile of the structure transfer member to the substrate; wherein the etching selectivity or selectivity of the structure transfer member in relation to the substrate is between 0.5 and 1.5. This method allows for etching deep into and through the substrate.

In other aspects, the present invention includes a method of etching a substrate, the method comprising the steps of providing a substrate, Adding a structure transfer member to the substrate, creating a profile in the structure transfer member to create a structure transfer member having a profile, and etching the substrate and the structure transfer member simultaneously thereby transferring the profile of the structure transfer member to the substrate; wherein the etching selectivity or selectivity of the structure transfer member in relation to the substrate is between 0.5 and 1.5.

The methods described herein are of use in the manufacturing of cutting edges for razors.

The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

While the specification concludes with claims particularly pointing out and distinctly claiming the subject matter which is regarded as forming the present invention, it is believed that the invention will be better understood from the following description which is taken in conjunction with the accompanying drawings in which like designations are used to designate substantially identical elements, and in which:

FIG. 1 is a process flow diagram of the preferred method;

FIG. 2A to 2H is a schematic view of each step of the preferred method for etching a substrate;

FIG. 3A to 3F is a schematic view of each step of an alternative method for etching a substrate;

FIG. 4A to 4I is a schematic view of each step of an alternative method for etching a substrate;

FIG. 5A to 5I shows a cavity mold process for creating a structure transfer member having a profile used to etch a substrate;

FIGS. 6A and 6B illustrate the fundamental etch parameters Selectivity and Anisotropy, their equations and their schematic influence on the etching profile;

FIG. 7A-7G are representative profiles that can be etched using the proposed process;

FIG. 8 is a cutting foil made using the proposed process;

FIG. 8A-8B are cross sections of the foil of FIG. 8; and

FIG. 9 is a number glossary of terms used in the FIGURES.

### DETAILED DESCRIPTION OF THE INVENTION

The present invention relates to a method of structuring a substrate. The substrate may be etched to form a cutting blade having a first face, a second face opposed to the first face and different from the first face as well as a cutting edge at the intersection of the first face and the second face.

The term “comprising” in the claims and in the description of this application has the meaning that further components are not excluded. Within the scope of the present invention, the term “consisting of” should be understood as preferred embodiment of the term “comprising”. If it is defined that a group “comprises” at least a specific number of components, this should also be understood such that a group is disclosed which “consists” preferably of these components.

In the following, the term “cross-sectional” refers to the cross-sectional plane perpendicular to the linear extension of the cutting edge (if the cutting edge is straight) or the tangent of the cutting edge (if the cutting edge is curved) and the first face.

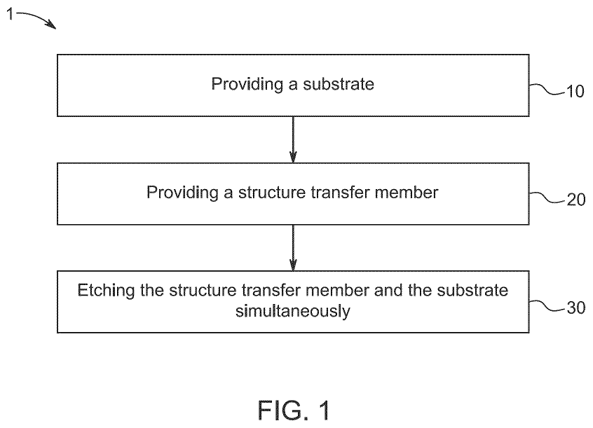

Disclosed is a method of etching a structure on a substrate through the use of a structure transfer member. As shown in FIG. 1, the method includes the steps of providing a substrate 10, providing a structure transfer member 20, and etching the structure transfer member and the substrate simultaneously 30. The structure transfer member may be profiled before or after it is provided and placed in contact with the substrate. The profile of the structure transfer member is the target profile to be transferred into the substrate. Subsequently, in step 30 the structure transfer member and the substrate are simultaneously etched via one or more process steps described below to transfer the target profile of the structure transfer member into the substrate. The etching selectivity or selectivity S plays an important role, as the final etch profile in the substrate will be dimensionally scaled by the selectivity. Thus, in order to have a “true” copy of the transfer member profile into the substrate, it is recommended to keep the selectivity close to 1. For this case the influence of a potential anisotropy A<1 on the residual profile of the substrate can be neglected. Optionally, after the transfer process is completed any remaining material or the transfer member may be removed.

The profile of the structure transfer member may be achieved by any known method inclusive of additive manufacturing or the addition of material, e.g. through 3d printing, electroplating, or deposition from the gas phase; subtractive manufacturing or the removal of material, e.g., by milling, grinding, electro-discharge machining, laser ablation, or etching, grey-scale lithography, interference lithography, gradual exposure of photoresist, or imprinting which involves the displacement of material, e.g. through embossing.

Embossing may use heat, pressure and or UV exposure. These processes involve a stamping tool (impression to create depth or height). Embossing may be used to create a profile in the structure transfer member as shown below.

The method disclosed provides many advantages including increasing the ease of manufacturing, the ability to create a smooth and sharp edge, that can be made from any substrate material, and the ability to create unique shapes inclusive of the creation of multiple different shapes in the same step or operation that are not limited in the manner shapes are limited by current etching or grinding processes. The resulting cutting blade is flexible in terms of design allowing for different blade/bevel profiles and lateral shapes (meaning in xy-direction). Additionally, the blade shapes are not limited to a straight linear shape but instead may be in the form of any 2-dimensional planar geometry (linear, non-linear, serrated, enclosed, variable thickness and variable bevel profiles). The cutting blade has a precisely defined, reproducible, smooth blade/bevel edge profile with sub-micron reproducibility that is not limited to a continuously inclining bevel. It is also possible to create additional micro- and/or macro-structures on the cutting blade bevel surfaces or edges, like teeth, holes, bumps or channels.

The disclosed method can be scaled to mass production at a relatively low production cost. The method creates the cutting blade by utilizing a quasi-three dimensional etch process that creates smooth non-ragged cutting edges defined by a section of two planes, the first face and the second face of the substrate rather than a line as in conventional photolithography. The method may utilize dry etching methods like e.g., RIE (Reactive Ion Etching) IBE, RIBE, ICP-RIE and/or Sputter Etching and may avoid wet etching process steps which typically involve a multitude of steps and chemicals that may be harmful to the environment.

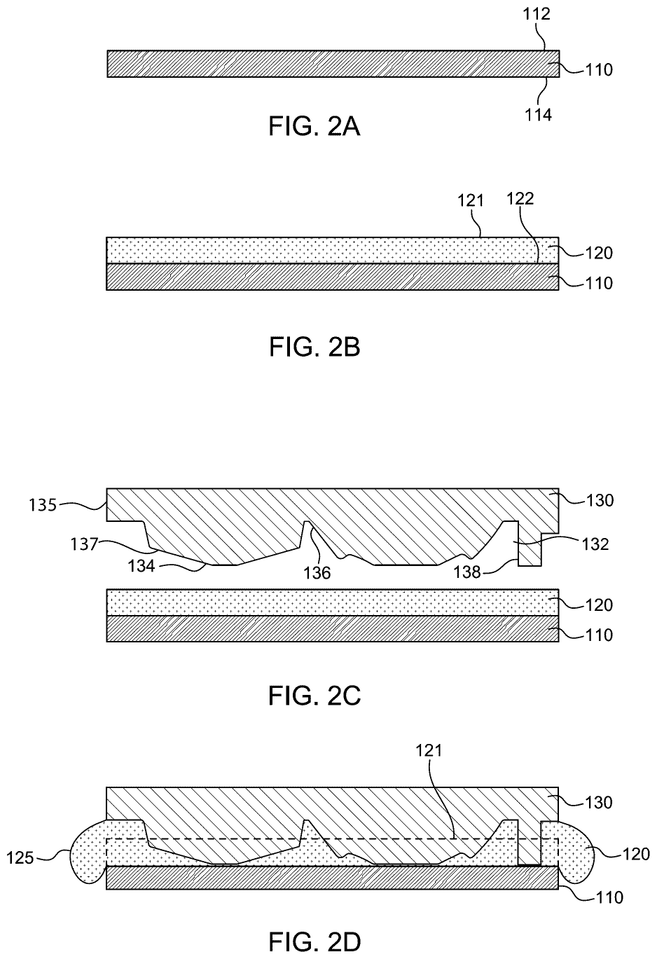

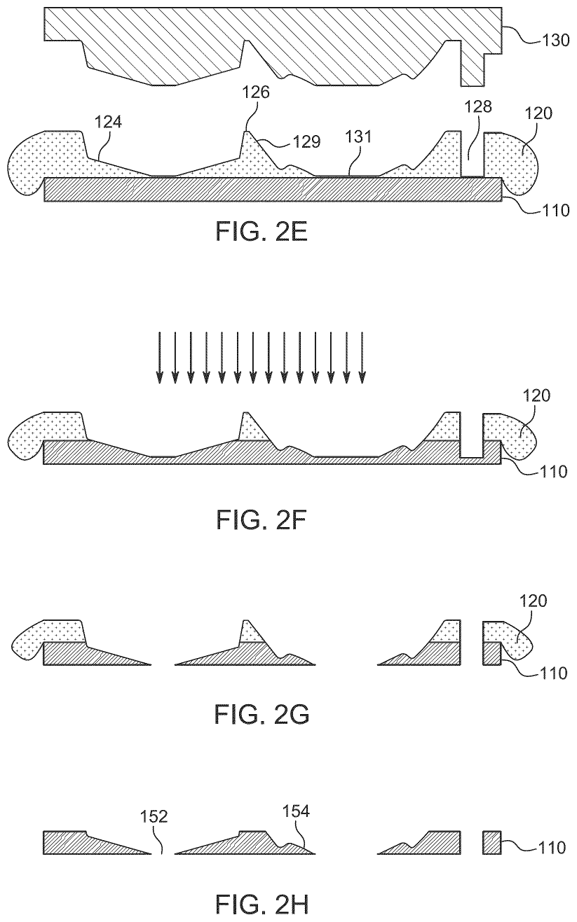

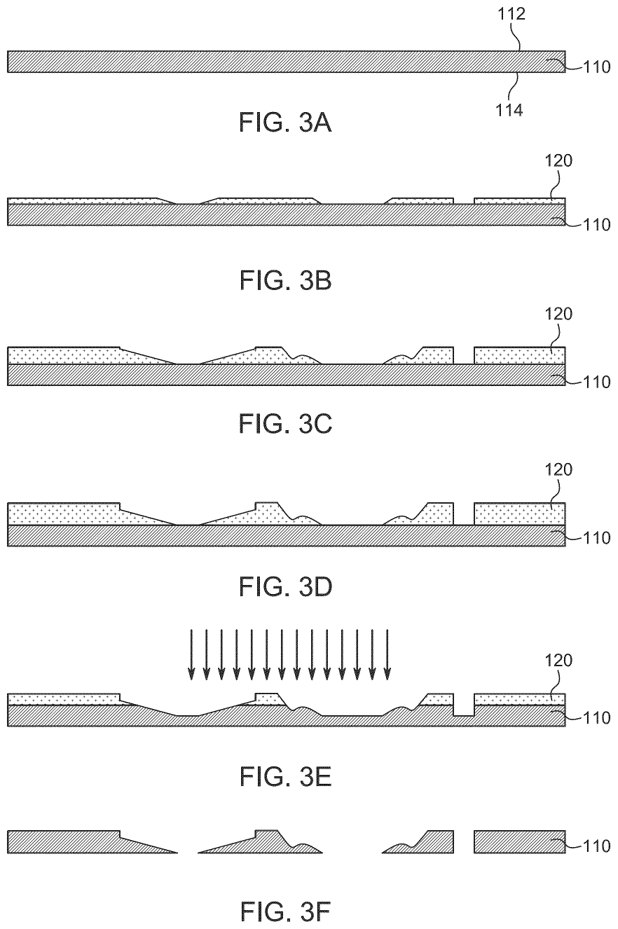

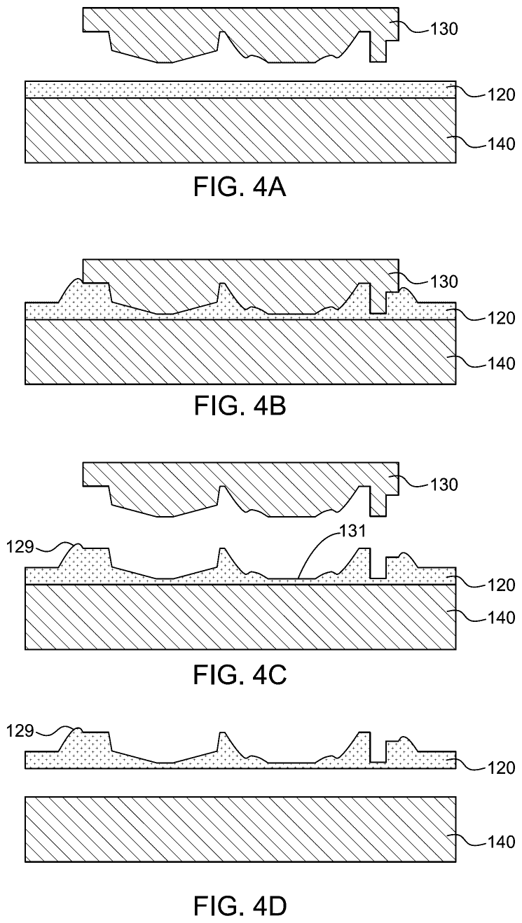

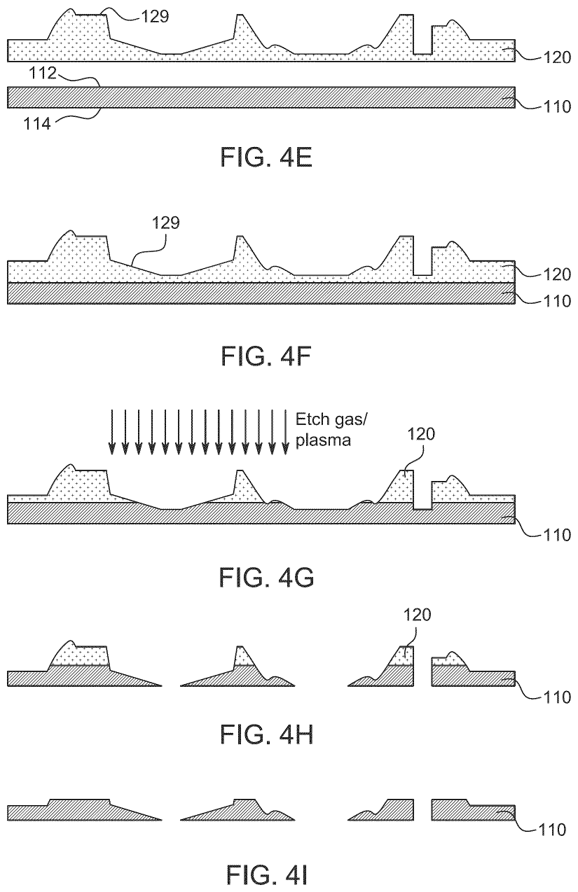

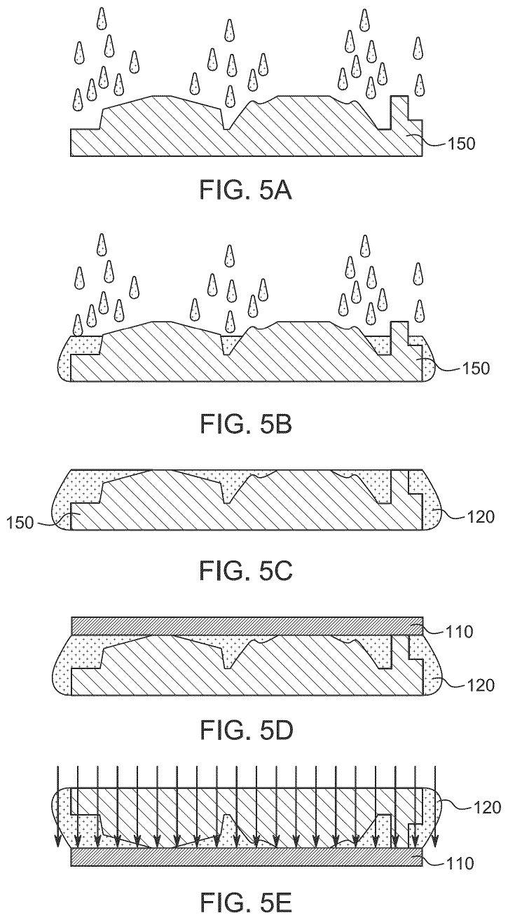

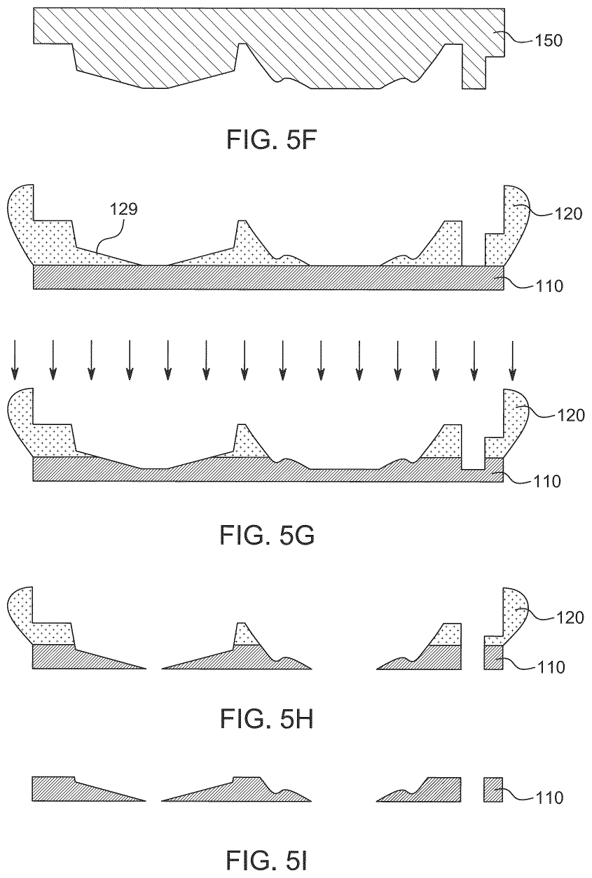

FIGS. 2 to 5 show alternative versions of the process. The distinction between the alternative process chains lies in the creation of the profile of the structure transfer member. The structured transfer member may be structured or profiled by the methods discussed below prior to being placed on the substrate and/or after being placed on the substrate depending on the chosen method of profiling and material properties. As described below, the material chosen for the structure transfer member may determine the method of making and profiling the structured transfer member. As shown in FIG. 2, the profile may be created using a stamp method after the structure transfer member is in contact with the substrate. As shown in FIG. 3, the profile of the structure transfer member may be created using additive manufacturing. Alternatively, the profile of the structure transfer member may be made prior to the step of being placed in contact with the substrate using either a stamping process as shown in FIG. 4, or a mold process as shown in FIG. 5.

FIG. 2 shows the process wherein the profile of the structure transfer member is created by a stamping tool. A stamping tool imprints via the displacement of material, e.g. through embossing. As shown in FIG. 2A, the first step is providing a substrate 110 having a first surface 112 and a second surface 114. The substrate may be a silicon wafer. Note also that, although the material described in this illustrative embodiment is silicon, any appropriate substrate material can be etched into cutting blade such as: metals, preferably titanium, nickel, chromium, niobium, tungsten, tantalum, molybdenum, vanadium, platinum, germanium, iron, and alloys thereof, in particular steel; ceramics comprising at least one element selected from the group consisting of carbon, nitrogen, boron, oxygen and combinations thereof, preferably silicon carbide, zirconium oxide, aluminum oxide, silicon nitride, boron nitride, tantalum nitride, AlTiN, TiCN, TiAlSiN, TiN, and/or TiB2; glass ceramics; preferably aluminum-containing glass-ceramics; composite materials made from ceramic materials in a metallic matrix (cermets); hard metals, preferably sintered carbide hard metals, such as tungsten carbide or titanium carbide bonded with cobalt or nickel; silicon or germanium, preferably with the crystalline plane parallel to the second face, wafer orientation <100>, <110>, <111> or <211>; single crystalline materials; glass or sapphire; polycrystalline or amorphous silicon or germanium; mono- or polycrystalline diamond, nano-crystalline and/or ultranano-crystalline diamond like carbon (DLC), adamantine carbon and combinations thereof.

The steels used for the substrate are preferably selected from the group consisting of 1095, 12C 27, 14C 28N, 154 CM, 3Cr 13MoV, 4034, 40X10C2M, 4116, 420, 440A, 440B, 440C, 5160, 5Cr15MoV, 8Cr 13MoV, 95X18, 9Cr18MoV, Acuto+, ATS-34, AUS-4, AUS-6 (=6A), AUS-8 (=8A), C75, CPM-10V, CPM-3V, CPM-D2, CPM-M4, CPM-S-30V, CPM-S-35VN, CPM-S-60V, CPM-154, Cronidur-30, CTS 204P, CTS 20CP, CTS 40CP, CTS B52, CTS B75P, CTS BD-1, CTS BD-30P, CTS XHP, D2, Elmax, GIN-1, H1, N690, N695, Niolox (1.4153), Nitro-B, S70, SGPS, SK-5, Sleipner, T6MoV, VG-10, VG-2, X-15T.N., X50CrMoV15, ZDP-189.

FIG. 2B shows the second step, providing a structure transfer member 120 without a profile having an outer surface 121 placed away from the substrate 110 and an inner surface 122 which is brought in contact with a surface (either the first 112 or second 114) of the substrate 110. The structure transfer member 120 is preferably a polymer that is applied as a solid film e.g. through lamination. Alternatively, the structure transfer member material may be applied as a liquid through spray-coating, dipping, or spin-coating followed by a curing (baking) step. The polymer may be selected from polymers such as NanoImprint lithography (NIL) photoresists, standard photoresists from Semiconductor Industry, LIGA (Lithographie, Galvanoformung, Abformung) resists (e.g. like SU8), PMMA resists or films, UV or thermal curable silicones or rubbers, inkjet printable polymers, 3d printable polymers, epoxies, polyolefins such as polypropylene (PP), polyvinyl chloride (PVC), polystyrene (PS), various polyesters and polycarbonate (PC) and other plastics preferentially as foils.

As shown in FIG. 2C, a stamping tool 130 is provided. The stamping tool 130 has a stamping tool profile 135. The stamping tool profile 135 may have straight sloped sections 134, curved sections with positive and negative slopes 136, or vertical sections 138, and/or combinations thereof. Said otherwise, the stamping tool comprises areas having curvatures, change in slope directions, inflection points 137, and combinations thereof.

The stamping or imprinting tool may be prepared through a separate operation, e.g., it may have been machined from a solid block of metal by a subtractive machining operation, e.g., milling, grinding, electro-discharge machining, laser ablation. As an alternative, the stamping tool can also be made from a polymer, e.g. like silicone, whose shape is replicated from a master tool e.g. made of non-ferrous metals (e.g. like tin, brass, copper, aluminum), steel or silicon, by embossing or molding. The stamping tool may be one of a plurality of stamps on a continuous wheel (not shown) thereby allowing an assembly line of structure transfer members being stamped as they pass under a stamping wheel. Alternatively, the stamp may be a single unit that is raised and lowered along a vertical axis that is perpendicular to the direction of travel of the substrate transfer material.

As shown in FIG. 2D, the stamping tool 130 stamps a profile into the structure transfer member 120. The amount of material of the structure transfer member should be chosen such that the material will fill the cavities 132 of the stamping tool as shown in FIG. 2D wherein material has crossed past the prior outer surface 121 (shown by a dotted line) of the structure transfer member 120. The structure transfer member may be chosen to have certain characteristics such as softness and pliability that allow it to be displaced. As shown in FIG. 2D, a portion of material of the structure transfer member may be expelled during the stamping process in the form of squeeze out 125 or excess. The tool is pressed into the polymer all the way through to the substrate surface to displace polymer material and thus create the true profile and shape in all 3 dimensions in the polymer laminate. In one embodiment, the amount of material used in the structure transfer member 120 is determined to eliminate any squeeze out 125. The amount of material may be controlled volumetrically. In an alternative embodiment, the stamp is designed to provide cavities 132 to accommodate material to move upwards and sideways into the stamping tool as shown in FIG. 2D.

Once the stamping tool is removed, as shown in FIG. 2E, the profile 129 is embossed such that it forms a mirror image in the structure transfer member. The profile 129 may comprise curvatures, changes in slope directions, inflection points, and combinations thereof.

The structure transfer member profile remains after the stamping tool is removed such that the profile creates a new outer surface of the structure transfer member which may be both below and above the original outer surface designated by 121. For example, as shown in FIG. 2E, each portion of the stamp identified (134, 136, and 138) shares a counterpart in the structure transfer member 120 as evidenced by 124, 126, and 128. Said otherwise, the stamping tool contains the inverse of the target profile and shape in all 3 dimensions, i.e. where the target profile or shape has a raised feature, the imprinting tool has a recess and vice-versa. The inverse of the target profile is also known as a “negative”, while the target profile is also known as a “positive”.

As shown in FIGS. 2F and 2G, the structure transfer member and substrate are then etched simultaneously 140 at defined rates. Once the target profile of the structure transfer member has been completely transferred into the substrate, any remaining portion of the structure transfer member may optionally be removed resulting in a final etched substrate as seen in FIG. 2H. As shown in FIG. 2H, the substrate comprises portions where it is etched completely to create a hole 152 and portions where it is partially etched 154.

As shown in FIG. 3A-3F, the structure transfer member 120 may be formed through the use of additive manufacturing directly on the substrate 110. This process is shown in FIG. 3B to FIG. 3D wherein material forming the structure transfer member is deposited or added onto the substrate 110 creating a profile. Once the profile is created, simultaneous etching which is exemplified by FIG. 3E is similar to that of FIG. 2F-2G with a final result exemplified by FIG. 3F.

FIG. 4A to 4I represents an alternative embodiment in which the structure transfer member 120 is profiled prior to being placed in contact with the substrate 110. As shown in FIG. 4A a stamping tool 130 is used to emboss the structure transfer member 120 on a backing 140. The backing may be any material such as, e.g., a metal, such as, e.g., steel, aluminum or an elastomer such as silicone.

The stamping process of FIG. 4 is similar to that of FIG. 2 wherein, as shown in FIGS. 4A and 4B, the stamping tool 130 embosses a profile into the structure transfer member 120. The amount of material of the structure transfer member should be chosen such that the material will fill the cavities of the stamping tool as shown in FIG. 4B. The structure transfer member may be chosen to have certain characteristics such as softness and pliability that allow it to be displaced. The tool is pressed into the polymer all the way through to the substrate surface to displace polymer material and thus create the true profile and shape in all 3 dimensions in the polymer laminate.

Once the stamping tool 130 is removed, as shown in FIG. 4C, the profile is embossed such that it forms a mirror image in the structure transfer member. The structure transfer member profile remains after the stamping tool is removed such that the profile creates a new outer surface of the structure transfer member which may be both below and above the original outer surface. Once the stamping tool is removed the structure transfer member may have one or more portions 131 that exhibit a minimal thickness. The minimal thickness represents the thinnest layer of material in the structure transfer member. The minimal thickness may be between 10 and 1000 micrometers, such as, e.g., 10 μm, 20 μm, 30 μm, 40 μm, 50 μm, 60 μm, 70 μm, 80 μm, 90 μm,100 μm, 200 μm, 300 microns, 400 μm, 500 μmicrons, 600 μm, 700 μm, 800 μm, 900 μm, such as, e.g., between 10 μm and 100 μm or up to 1000 μm. Finally, as shown in FIG. 4D the structure transfer member having a profile is removed from the backing 140 and is now available to be brought in contact with the substrate as shown in FIG. 4E-4F. Simultaneous etching of the substrate and the profiled transfer member is schematically shown in FIG. 4F-4I accordingly to FIG. 2F-2G and FIG. 3E. As shown in FIG. 4H, the structure transfer member 120 is continuously removed during the process and eventually not present as shown in FIG. 4I, leaving only the remaining substrate 110 which has been etched.

FIG. 5A-5I show an alternative process wherein a free-flowing or viscous curable liquid polymer is used to fill a cavity mold 150 as shown in FIGS. 5A-5C. Once the cavities are filled a substrate 110 may be placed in contact with the polymer as shown in FIG. 5D. The polymer is then cured using any known curing process such as, e.g., heat, ultraviolet light, or infrared light. Once cured, the cavity mold 150 is removed as shown in FIG. 5F leaving behind a polymer that is a structured transfer member 120 having a profile 129. FIGS. 5G and 5H show the etching process while FIG. 5I shows a finished etched substrate.

Alternatively, the profile of the structure transfer member may be created through the use of subtractive manufacturing. As used herein “subtractive manufacturing” involves the removal of material, e.g., by milling, grinding, electro-discharge machining, laser ablation, or etching. Subtractive removal of material from the transfer member may be achieved by utilizing a (transfer) tool, having the negative pattern, thus, cavities and hot embossing into the polymer or imprinting (nano-imprint lithography NIL) it into the structure transfer member e.g. be utilizing photolithography and/or temperature for polymerization followed by removal of the transfer-tool.

As discussed above, the subtractive removal of material from the transfer member may be achieved by gradual exposure of photoresist e.g. by grayscale lithography, gradual laser lithography, interference lithography and movement of the structure transfer member during exposure followed by development of photoresist.

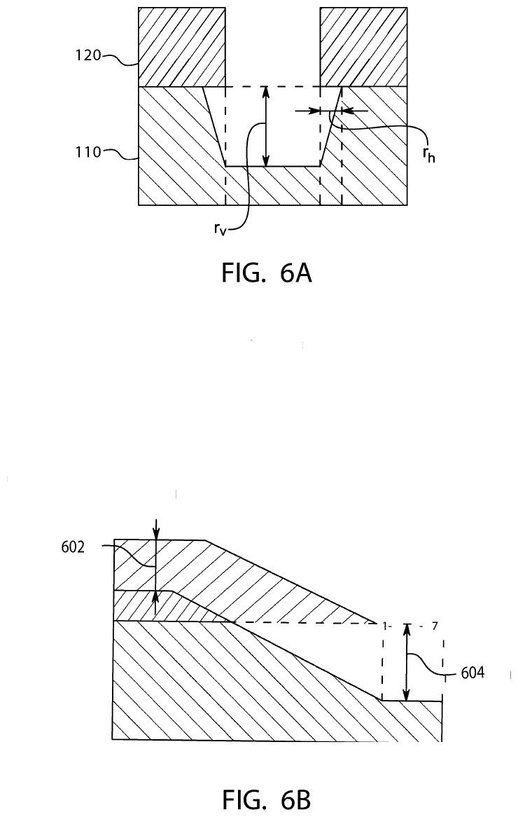

Etching may be done in a vacuum chamber as described below. The etching process to transfer the profile of the structure transfer member may be done in two ways. The first is by dry etching. Dry etching may be done through the use of a gaseous etchant with etch rates of the structured transfer member material and the substrate material that are approximately the same, i.e., the selectivity is between 0.5 and 1.5, preferably between 0.75 and 1.25, more preferably between 0.9 and 1.1 or approximately 1. It is understood that, depending on the structured transfer member profile and the substrate, one may choose a selectivity that allows for controlled etching by use of the chosen chemistry or volumetric flow of gases (gas composition) and process parameters like pressure, electrical power and bias voltage. The gaseous etchant may be delivered utilizing ion bombardment to steer or adjust a desired selectivity e.g. IBE. One of ordinary skill in the art would know that selectivity regarding etching relates to the relationship of the structure transfer member and the substrate in terms of their respective vertical etch rates rv for the structure transfer member 602 and the rv for the substrate 604. This is demonstrated by the equation and shown in FIG. 6B:

$$Selectivity S = {rv}_{structure transfer member} / {rv}_{substrate}$$

The selection of the gaseous etchant will depend on the substrate material and the structure transfer member material. In an embodiment, the gaseous etchant may be selected to be combined with a reactive and physical component e.g. RIE, RIBE to steer or adjust a desired selectivity. For example, one may utilize a dry etching process of high anisotropy e.g. RIE with a physical component.

The controlled matching of selectivity as a means to control uniform simultaneous etching of the substrate and the structure transfer member is realized by sacrificing the transfer member material. This is in strong contrast to common etch strategies, e.g. like in semiconductor industry, wherein a parasitic attack of the mask (here: structured transfer member) is unwanted. Thus, typical semiconductor processes are trimmed to the highest possible selectivity. Anisotropy depends on the vertical etch rate rv and the horizontal etch rate rh in a place perpendicular to the vertical axis and is defined as

$$Anisotropy A = 1 - ( rh / rv )$$

As shown in FIG. 6A, anisotropy only factors the rate of etching of the substrate in the horizontal and vertical direction. However, due to the use of the transfer member (mask), Anisotropy is limited in terms of the profiles that the process can create. As previously stated, the anisotropy is of minor importance as long as the selectivity is close to 1.

After the profile of the structure transfer member has been etched into the substrate, less than 20% of the structure transfer member should remain such as, for example, between 0.1% of the structure transfer member and 20% of the structure transfer member, between 0.1% of the structure transfer member and 10%, between 0.1% of the structure transfer member and 5%, e.g. 1%, 2%, 3%, 4%, 5%, 6%, 7%, 8%, 9%, 10%, 11%, 12%, 13%, 14%, 15%, 16%, 17%, 18%, 19% or 20%. In an embodiment, the structure transfer member is completely removed when etching through the substrate is complete.

It has further been found that it is beneficial to match the thickness of the structure transfer member and the substrate such that the thickness of the structure transfer member is between 25% and 200% of the thickness of the substrate, such as, e.g., between 50% and 150%, between 75% and 125%, or between 90% and 110% of the thickness of the substrate.

Any residual portion of the structure transfer member may be stripped after etching. In an embodiment, 0% of the structure transfer member remains when the substrate is finished being etched. Stated otherwise, one may choose the initial thickness of the structure transfer member and the gaseous etchant so that the structure transfer member is completely etched away during the process and costly additional stripping processes are omitted.

Without being bound by theory, it has been found that by matching the selectivity of the structure transfer member and the substrate and that by choosing the gaseous etchant inclusive of amounts and ratios used to etch the substrate and the structure transfer member having a profile, one can control the rate at which the materials are etched in such a manner that the profile of the structure transfer member is copied into the substrate under the structure transfer member.

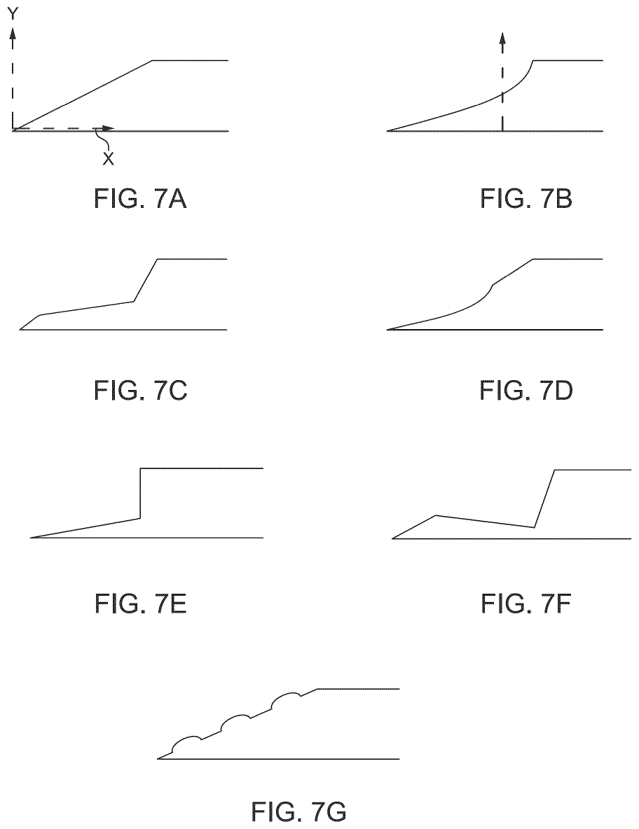

The process described above is not limited to profiles having straight lines. This provides an advantage over masked etching that traditionally relies on a mask to protect a portion of a substrate while etching. Masked etching traditionally utilizes the same mask multiple times in a process. Unlike traditional masked etching shapes such as the one shown in FIG. 7A wherein the profile has a monotonically increasing slope in the x-direction, the current process allows one to create shapes such as those shown in FIGS. 7B-7G. As shown in FIG. 7B-7G, the method described herein allows for the creation of curves (7B, 7D, and 7G), structures that have a change in slope directions such as 7F wherein the profile shifts from a downward or negative slope to a rising or positive slope, and profiles such as the one shown for 7G which exhibits an undulating pattern along the x-axis while rising along the y-axis.

Surprisingly, and without being bound by theory, the ability to create profiles in a substrate such as those shown in FIGS. 7B-7G are particularly of interest regarding silicon wafers. Silicon profiles are traditionally limited to either straight lines in a vertical direction and the shape of the crystal structure. Unlike prior methods used to etch silicon, the method described herein allows for the creation of complex profiles in silicon that had not been previously possible inclusive of a silicon wafer having an edge etched whose profile exhibits one or more curvatures, one or more directional slope changes, or combinations thereof.

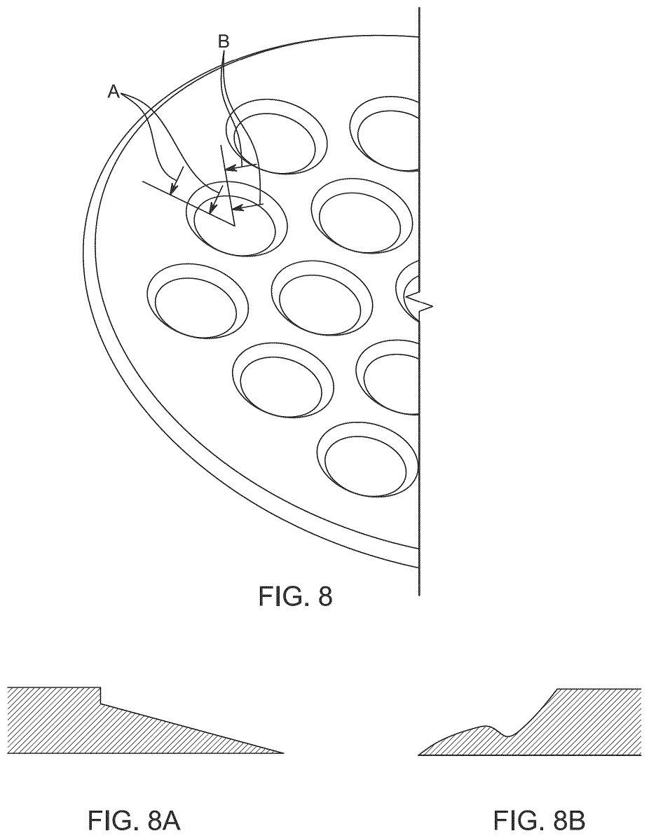

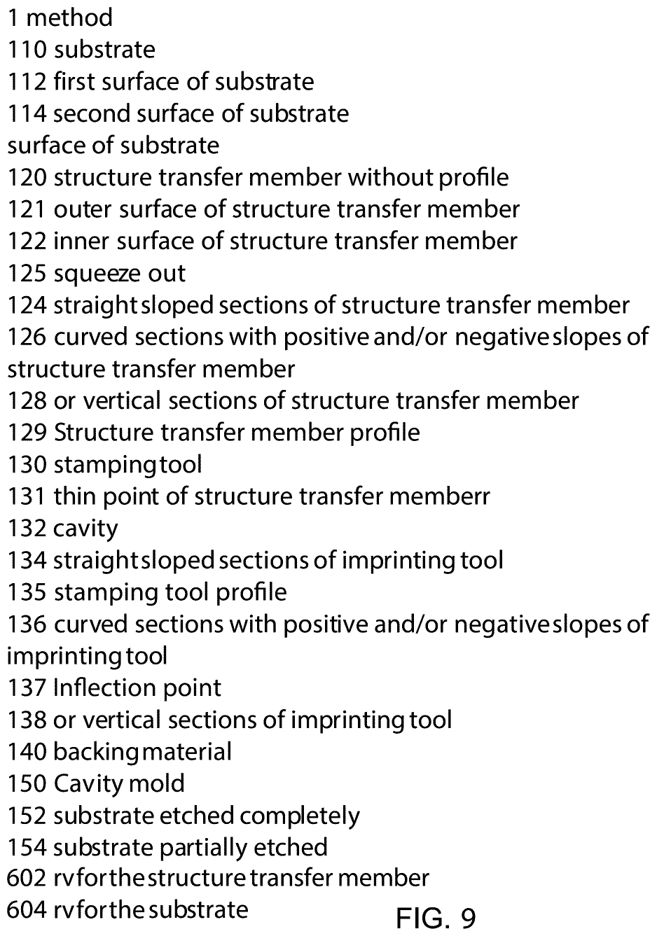

Additionally, unlike traditional razor blade cutting edges which are formed on a strip, the current process may be used to make multiple cutting apertures in a sheet such as the one shown in FIG. 8. Due to the use of the structure transfer member, each aperture may have a different size and geometric shape. Additionally, within the same shape (e.g. a circle) the cutting edge formed on one portion of the circle may be distinctly different than in another part of the same circle as shown by the cross sections taken at FIG. 8A and FIG. 8B.
A. A method of etching a substrate, the method comprising:
   Providing a substrate
   providing a structure transfer member having a profile,
   placing the structure transfer member in contact with the substrate,
   etching the substrate and the structure transfer member simultaneously thereby transferring the profile of the structure transfer member to the substrate,
   wherein the selectivity of the structure transfer member in relation to the substrate is between 0.5 and 1.5.
B. The method of paragraph A, wherein the structure transfer member is profiled using the following steps:
   Providing a backing material;
   Providing the structure transfer member without a profile;
   Embossing a profile into the structure transfer member to create a structure transfer member having a profile;
   Peeling the structure transfer member from the backing material.
C. The method of any of paragraphs A to B, wherein the structure transfer member comprises a minimum thickness along a (vertical) z-axis of 10 to 30 micrometers.
D. The method of any of paragraphs A to C, wherein the selectivity is between 0.9 and 1.1.
E. The method of any of paragraphs A to D, wherein the substrate is selected from the group comprising of silicon, metals, metal oxides, cemented carbides, carbide, diamond, ceramics, or combinations thereof
F. The method of any of paragraphs A to E, wherein the structure transfer member is a polymer selected from the group comprising of NanoImprint lithography (NIL) photoresists, standard photoresists from Semiconductor Industry, LIGA (Lithographie, Galvanoformung, Abformung) resists (e.g. like SU8), PMMA resists or films, UV or thermal curable silicones or rubbers, inkjet printable polymers, 3d printable polymers, epoxies, polyolefins such as polypropylene (PP), polyvinyl chloride (PVC), polystyrene (PS), various polyesters and polycarbonate (PC) and other plastics.
G. The method of any of paragraphs A to F, wherein the structure transfer member is profiled after contacting the substrate.
H. The method of paragraph G, wherein the structure transfer member is profiled using a stamping tool.
I. The method of any of paragraphs A to H, wherein the profile of the structure transfer member comprises one of curvatures, change in slope directions, inflection points, and combinations thereof.
J. The method of any of paragraphs A to I, wherein a residual thickness of the structure transfer member remains after etching, wherein the residual thickness is between 0.1% of the structure transfer member and 5% of the structure transfer member.

The illustrations presented herein are not intended to be actual views of any substrate, apparatus (e.g., device, system, etc.), or method, but are merely idealized and/or schematic representations that are employed to describe and illustrate various embodiments of the disclosure.

The dimensions and values disclosed herein are not to be understood as being strictly limited to the exact numerical values recited. Instead, unless otherwise specified, each such dimension is intended to mean both the recited value and a functionally equivalent range surrounding that value. For example, a dimension disclosed as “40 mm” is intended to mean “about 40 mm” or ±10% of the disclosed dimension.

Every document cited herein, including any cross referenced or related patent or application and any patent application or patent to which this application claims priority or benefit thereof, is hereby incorporated herein by reference in its entirety unless expressly excluded or otherwise limited. The citation of any document is not an admission that it is prior art with respect to any invention disclosed or claimed herein or that it alone, or in any combination with any other reference or references, teaches, suggests or discloses any such invention. Further, to the extent that any meaning or definition of a term in this document conflicts with any meaning or definition of the same term in a document incorporated by reference, the meaning or definition assigned to that term in this document shall govern.

While particular embodiments of the present invention have been illustrated and described, it would be obvious to those skilled in the art that various other changes and modifications can be made without departing from the spirit and scope of the invention. It is therefore intended to cover in the appended claims all such changes and modifications that are within the scope of this invention.

What is claimed is:

1. A method of etching a substrate, the method comprising:
providing a substrate;
providing a structure transfer member having a profile;
placing the structure transfer member in contact with the substrate;
etching the substrate and the structure transfer member simultaneously thereby transferring the profile of the structure transfer member to the substrate;
wherein the selectivity of the structure transfer member in relation to the substrate is between 0.5 and 1.5.

2. The method of claim 1, wherein the structure transfer member is profiled using the following steps:
providing a backing material;
providing the structure transfer member without a profile;
placing the structure transfer member in contact with the backing;
embossing a profile into the structure transfer member to create a structure transfer member having a profile;
removing the structure transfer member from the backing material.

3. The method of claim 2, wherein the structure transfer member comprises a minimum thickness along a vertical axis of 1 micrometer to 200 micrometers.

4. The method of claim 1, wherein the selectivity is between 0.75 and 1.25.

5. The method of claim 1, whereby the thickness of the structure transfer member ranges between 25 and 200% of the thickness of the substrate.

6. The method of claim 1, wherein the substrate is selected from the group comprising of silicon, metals, metal oxides, cemented carbides, carbide, diamond, ceramics, metals, preferably titanium, nickel, chromium, niobium, tungsten, tantalum, molybdenum, vanadium, platinum, germanium, iron, and alloys thereof, in particular steel; ceramics comprising at least one element selected from the group consisting of carbon, nitrogen, boron, oxygen and combinations thereof; glass ceramics; composite materials made from ceramic materials in a metallic matrix (cermets); hard metals; silicon or germanium; single crystalline materials; glass or sapphire; polycrystalline or amorphous silicon or germanium; mono- or polycrystalline diamond, nano-crystalline and/or ultranano-crystalline diamond like carbon (DLC), adamantine carbon and combinations thereof.

7. The method of claim 1, wherein the structure transfer member is a polymer selected from the group comprising of NanoImprint lithography (NIL) photoresists, standard photoresists from Semiconductor Industry, LIGA (Lithographie, Galvanoformung, Abformung) resists (e.g. like SU8), PMMA resists or films, UV or thermal curable silicones or rubbers, inkjet printable polymers, 3d printable polymers, epoxies, polyolefins such as polypropylene (PP), polyvinyl chloride (PVC), polystyrene (PS), various polyesters and polycarbonate (PC) and other plastics.

8. The method of claim 1, wherein the profile of the structure transfer member comprises one of curvatures, change in slope directions, inflection points, and combinations thereof.

9. The method of claim 1, wherein a residual of the structure transfer member remains after etching, wherein the residual is between 0.1% of the thickness of the structure transfer member and 10% of the thickness of the structure transfer member.

10. A method of etching a substrate, the method comprising:
providing a substrate;
adding a structure transfer member to the substrate;
creating a profile on the structure transfer member;
etching the substrate and the structure transfer member simultaneously thereby transferring the profile of the structure transfer member to the substrate;
wherein the selectivity of the structure transfer member in relation to the substrate is between 0.5 and 1.5.

11. The method of claim 10, wherein the structure transfer member is profiled using a stamping tool.

12. The method of claim 11, wherein the structure transfer member comprises a minimum thickness along a vertical axis of 1 micrometer to 200 micrometers.

13. The method of claim 10, wherein the selectivity is between 0.75 and 1.25.

14. The method of claim 10, wherein the substrate is selected from the group comprising of silicon, metals, metal oxides, cemented carbides, carbide, diamond, ceramics, metals; ceramics comprising at least one element selected from the group consisting of carbon, nitrogen, boron, oxygen and combinations thereof; glass ceramics; composite materials made from ceramic materials in a metallic matrix (cermets); hard metals, preferably sintered carbide hard metals, such as tungsten carbide or titanium carbide bonded with cobalt or nickel; silicon or germanium; single crystalline materials; glass or sapphire; polycrystalline or amorphous silicon or germanium; mono- or polycrystalline diamond, nano-crystalline and/or ultranano-crystalline diamond like carbon (DLC), adamantine carbon and combinations thereof.

15. The method of claim 10, wherein the structure transfer member is a polymer selected from the group comprising of NanoImprint lithography (NIL) photoresists, standard photoresists from Semiconductor Industry, LIGA (Lithographie, Galvanoformung, Abformung) resists (e.g. like SU8), PMMA resists or films, UV or thermal curable silicones or rubbers, inkjet printable polymers, 3d printable polymers, epoxies, polyolefins such as polypropylene (PP), polyvinyl chloride (PVC), polystyrene (PS), various polyesters and polycarbonate (PC) and other plastics.

16. The method of claim 10, wherein the structure transfer member is profiled according to the following steps:
providing a stamping tool; and
embossing a profile on the structure transfer member using said stamping tool.

17. The method of claim 16, wherein the stamping tool is on a wheel comprising a plurality of stamping tools.

18. The method of claim 10, wherein a residual of the structure transfer member remains after etching, wherein the residual is between 0.1% of the structure transfer member and 10% of the structure transfer member.

19. The method of claim 10, wherein the step of creating a profile on the structure transfer member further comprises providing the structure transfer member in a mold.

20. The method of claim 19, wherein providing a structure transfer member further comprises:
providing a mold cavity;
filling the mold cavity with a liquid polymer;
placing the filled mold cavity in contact with the substrate, and curing the liquid polymer to form a structure transfer member having a profile.
